(19) United States
(12) Patent Application Publication
(10) Pub. No.: US 2026/0266913 A1
(43) Pub. Date: Sep. 10, 2026

(54) BATTERY MANAGEMENT SYSTEM EQUIPPED WITH AUXILIARY BATTERY CELL MONITORING FUNCTION

(71) Applicants: HYUNDAI MOTOR COMPANY, SEOUL (KR); KIA CORPORATION, SEOUL (KR)

(72) Inventors: Hyunki Cho, Hwaseong-si (KR); Jonghu Yoon, Hwaseong-si (KR); Jeongwon Han, Hwaseong-si (KR)

(73) Assignees: HYUNDAI MOTOR COMPANY, SEOUL (KR); KIA CORPORATION, SEOUL (KR)

(21) Appl. No.: 19/261,073

(22) Filed: Jul. 7, 2025

(30) Foreign Application Priority Data
Mar. 10, 2025 (KR) 10-2025-0030619

(51) Int. Cl. G01R 31/382; B60L 3/00; B60L 50/60; B60R 16/033

(52) U.S. Cl. CPC G01R 31/382; B60L 3/0046; B60L 50/60; B60R 16/033

(57) ABSTRACT

A battery management system (BMS) equipped with an auxiliary battery cell monitoring function may include a power supply circuit configured to receive power from an auxiliary battery and supply the power to the BMS, a controller configured to determine states of battery cells of a high-voltage battery module and the auxiliary battery based on information obtained by monitoring the battery cells of the high-voltage battery module and the battery cells of the auxiliary battery, and an isolation circuit configured to isolate respective grounds (GNDs) of the power supply circuit and an auxiliary battery cell monitoring unit configured to monitor battery cells of the auxiliary battery.

### CROSS REFERENCE TO RELATED APPLICATIONS

This present application claims the benefit of priority to Korean Patent Application No. 10-2025-0030619, filed on Mar. 10, 2025, in the Korean Intellectual Property Office, the entire disclosure of which is incorporated herein by reference.

### FIELD

The present disclosure relates to a battery management system, and more particularly, to a battery management system (BMS) configured to monitor battery cells in a high-voltage battery module and further provided with a function for monitoring battery cells of an auxiliary battery, and capable of operating stably.

### BACKGROUND

The core competitiveness of electric vehicles (EV), including hybrid electric vehicles (HEV) and plug-in hybrid electric vehicles (PHEV), lies in their driving range, and sufficient space should be available to accommodate as many batteries as possible.

In this context, there is a recent trend of replacing the existing 12V lead-acid (Pb) auxiliary battery installed in electric vehicles with a lithium-ion (Li-ion) battery to improve space utilization and reduce vehicle weight.

When designing and applying an integrated battery system that includes a high-voltage battery module and a 12V lithium auxiliary battery, the auxiliary battery used to supply power to vehicle controllers requires a stable power supply. Accordingly, monitoring of parameters such as voltage and temperature of the battery cells within the auxiliary battery is required.

Although it is possible to provide a separate battery management system (BMS) to monitor the battery cells of the 12V lithium auxiliary battery, such an approach is not appropriate given the very limited space available in electric vehicles.

Accordingly, there is a need for a solution in which the existing battery management system (BMS), which monitors battery cells within the high-voltage battery module, is also equipped with a monitoring function for the battery cells of the 12V lithium auxiliary battery integrated into the battery system, and is capable of performing such monitoring.

However, in an integrated battery system including the high-voltage battery module and the 12V lithium auxiliary battery, no specific technical solution has been proposed that enables the BMS, which monitors battery cells in the high-voltage battery module, to also perform a function of monitoring battery cells of the auxiliary battery while operating stably without being damaged.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

The present disclosure is directed to providing a battery management system (BMS) for an integrated battery system including a high-voltage battery module and an auxiliary battery (e.g., a 12V lithium battery), the BMS being configured to monitor not only cells of the high-voltage battery module, but also battery cells of the auxiliary battery, and to operate in a stable manner.

An aspect of the present disclosure may provide a battery management system (BMS) equipped with an auxiliary battery cell monitoring function, the BMS including a power supply circuit configured to receive power from an auxiliary battery and supply the power to the battery management system, a controller configured to determine a state of each of a plurality of battery cells of a high-voltage battery module and a state of the auxiliary battery based on information obtained by monitoring the plurality of battery cells of the high-voltage battery module and the plurality of battery cells of the auxiliary battery, and a a separation circuit configured to prevent electrical connection between a ground (GND) of the power supply circuit and a ground of an auxiliary battery cell monitoring unit configured to monitor the plurality of battery cells of the auxiliary battery, based on a potential difference between the ground of the power supply circuit and the ground of the auxiliary battery cell monitoring unit.

The separation circuit may include an isolation circuit configured to isolate the ground of the power supply circuit and the ground of the auxiliary battery cell monitoring unit.

The GND of the power supply circuit may be VEHICLE_CHASSIS_GND, and the GND of the auxiliary battery cell monitoring unit may be connected to the VEHICLE_CHASSIS_GND when the auxiliary battery is mounted in a vehicle, and wherein the GND of the auxiliary battery cell monitoring unit is connected to a BSA (battery system assembly)_CHASSIS_GND when the auxiliary battery is not mounted in the vehicle.

The isolation circuit may be configured to isolate, on a board of the BMS, a portion where the power supply circuit and the controller are mounted from a portion where the auxiliary battery cell monitoring unit is mounted, to provide a communication path between the controller and the auxiliary battery cell monitoring unit using an isolation communication circuit, and to isolate the ground of the power supply circuit and the ground of the auxiliary battery cell monitoring unit.

The isolation communication circuit may be configured to provide the communication path between the controller and the auxiliary battery cell monitoring unit using a communication isolation capacitor.

A negative terminal of the auxiliary battery may be connected to the BSA_CHASSIS_GND, and may be connected to the VEHICLE_CHASSIS_GND via a separate installation cable when the auxiliary battery is mounted in the vehicle.

The separation circuit may include a non-isolation circuit configured to adjust a potential difference between the ground of the power supply circuit and the ground of the auxiliary battery cell monitoring unit.

The non-isolation circuit may be configured to connect a GND plane of the power supply circuit and a GND plane of the auxiliary battery cell monitoring unit at a single point using a resistor, and to reduce a potential difference between the ground of the power supply circuit and the ground of the auxiliary battery cell monitoring unit through the resistor.

Another aspect of the present disclosure may provide a battery management system for managing an integrated battery system assembly (BSA) including a high-voltage battery module and an auxiliary battery, the battery management system including a power supply circuit configured to receive power from the auxiliary battery and to supply the power to the battery management system (BMS), and an isolation circuit configured to isolate a ground (GND) of the power supply circuit and a ground of an auxiliary battery cell monitoring unit configured to monitor battery cells of the auxiliary battery, to prevent electrical connection between the ground of the power supply circuit and the ground of the auxiliary battery cell monitoring unit within a board of the BMS when the auxiliary battery is not mounted in a vehicle, and is further configured to prevent a load current of the auxiliary battery from flowing into the board of the BMS when the auxiliary battery is mounted in the vehicle.

Still another aspect of the present disclosure may provide a battery management system for managing an integrated battery system assembly (BSA) including a high-voltage battery module and an auxiliary battery, the battery management system including a power supply circuit configured to receive power from the auxiliary battery and to supply the power to the battery management system (BMS), and a non-isolation circuit configured to adjust a potential difference between a ground (GND) of the power supply circuit and a ground of an auxiliary battery cell monitoring unit configured to monitor battery cells of the auxiliary battery, to prevent electrical connection between the ground of the power supply circuit and the ground of the auxiliary battery cell monitoring unit within a board of the BMS when the auxiliary battery is not mounted in a vehicle, and further configured to prevent a load current of the auxiliary battery from flowing into the board of the BMS when the auxiliary battery is mounted in the vehicle.

According to embodiments of the present disclosure, a battery management system (BMS) for an integrated battery system including a high-voltage battery module and an auxiliary battery (e.g., a 12V lithium battery) may be configured to monitor not only the cells of the high-voltage battery module but also the battery cells of the auxiliary battery, and to operate in a stable manner.

Accordingly, embodiments of the present disclosure may provide an effect of preventing an auxiliary battery from being discharged in a standalone state of the integrated battery system and, furthermore, preventing damage to a BMS board caused by load current from the auxiliary battery flowing into the BMS board due to a fault in the installation cable or bolting (e.g., cable disconnection or increased resistance) used to mount the auxiliary battery in the vehicle.

Aspects of the present disclosure are not limited to those mentioned above, and other aspects and advantages not mentioned above will be understood from the following description, and become more apparent from the exemplary embodiments. Moreover, aspects of the present disclosure may be realized by the means and combinations thereof indicated in claims.

### BRIEF DESCRIPTION OF THE FIGURES

The foregoing and other aspects, features, and advantages, as well as the following detailed description of the embodiments, will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 illustrates a structure of an integrated battery system according to one embodiment of the present disclosure.

FIG. 2 illustrates a circuit configuration of an integrated battery system according to one embodiment of the present disclosure.

FIG. 3 illustrates a situation where an auxiliary battery is discharged and a BMS is damaged in an integrated battery system.

FIGS. 4 and 5 illustrate an isolation circuit in a BMS equipped with an auxiliary battery cell monitoring function according to one embodiment of the present disclosure.

FIGS. 6 and 7 illustrate a non-isolation circuit in a BMS equipped with an auxiliary battery cell monitoring function according to another embodiment of the present disclosure.

### DETAILED DESCRIPTION

Hereinafter, embodiments disclosed in the present document will be described in detail with reference to the accompanying drawings. Like reference numerals designate like elements, and redundant descriptions thereof will be omitted. Further, such as "module" and a "unit", suffixes for components used in the following description are given or mixed and used by considering easiness in preparing a specification and do not have a meaning or role distinguished from each other in themselves. In addition, in describing an embodiment disclosed in the present document, if it is determined that a detailed description of a related art incorporated herein unnecessarily obscure the gist of the embodiment, the detailed description thereof will be omitted. Furthermore, it should be understood that the appended drawings are intended only to help understand embodiments disclosed in the present document and do not limit the technical principles and scope of the present disclosure; rather, it should be understood that the appended drawings include all of the modifications, equivalents or substitutes described by the technical principles and belonging to the technical scope of the present disclosure.

Although the terms first, second, and the like, may be used herein to describe various elements, these elements should not be limited by these terms. These terms are generally only used to distinguish one element from another.

When an element or layer is referred to as being "on," "engaged to," "connected to," or "coupled to" another element or layer, it may be directly on, engaged, connected, or coupled to the other element or layer, or intervening elements or layers may be present. In contrast, when an element is referred to as being "directly on," "directly engaged to," "directly connected to," or "directly coupled to" another element or layer, there may be no intervening elements or layers present.

The term “unit” or “module” used in this specification signifies one unit that processes at least one function or operation, and may be realized by hardware, software, or a combination thereof. The operations of the method or the functions described in connection with the forms disclosed herein may be embodied directly in a hardware or a software module executed by a processor, or in a combination thereof.

For purposes of this application and the claims, using the exemplary phrase "at least one of: A; B; or C" or "at least one of A, B, or C," the phrase means "at least one A, or at least one B, or at least one C, or any combination of at least one A, at least one B, and at least one C. Further, exemplary phrases, such as "A, B, and C", "A, B, or C", "at least one of A, B, and C", "at least one of A, B, or C", etc. as used herein may mean each listed item or all possible combinations of the listed items. For example, "at least one of A or B" may refer to (1) at least one A; (2) at least one B; or (3) at least one A and at least one B.

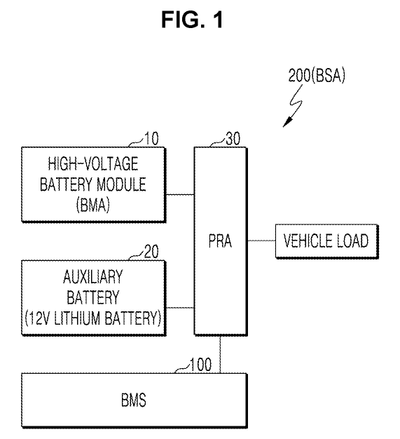

Hereinafter, a battery management system equipped with an auxiliary battery cell monitoring function according to embodiments of the present disclosure is described in detail with reference to FIGS. 1-7.

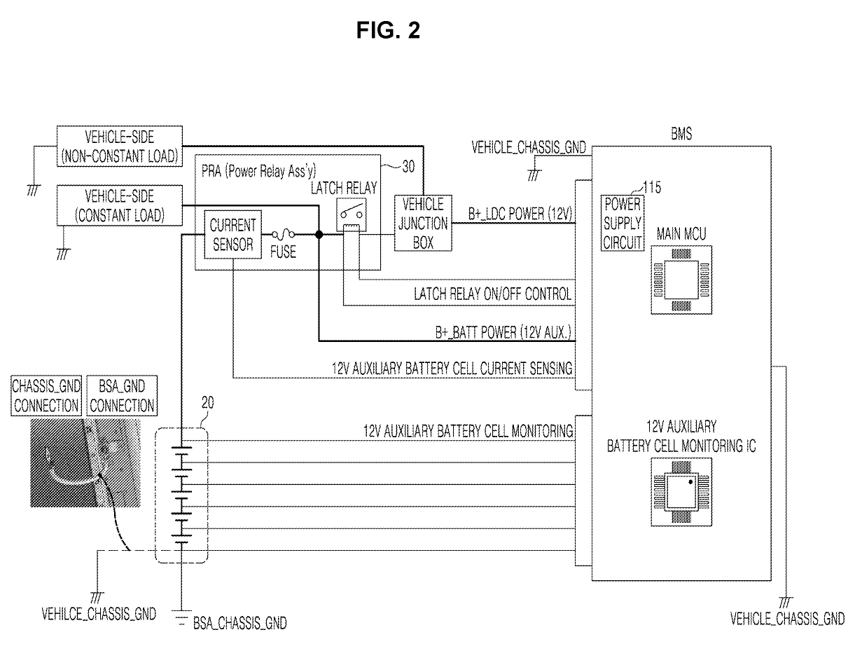

Before the detailed description of the present disclosure, a structure of an integrated battery system according to one embodiment of the present disclosure is described with reference to FIG. 1. The structure and circuit configuration of the integrated battery system, which are described below with reference to FIGS. 1 and 2, may also be regarded as proposed aspects of the present disclosure.

The present disclosure relates to an integrated battery system (hereinafter, referred to as a battery system assembly (BSA)) designed to include a high-voltage battery module and an auxiliary battery (e.g., a 12V lithium battery). For convenience of explanation, the following description will refer to a 12V lithium auxiliary battery.

In this regard, FIG. 1 illustrates a structure of a BSA 200 according to one embodiment of the present disclosure.

As illustrated in FIG. 1, an integrated battery system, i.e., the BSA 200, may include a battery module assembly (BMA) 10, a 12V lithium auxiliary battery 20, a power relay assembly (PRA) 30, and a battery management system (BMS) 100.

The PRA 30 may include electrical components such as a current sensor, a latch relay, and a fuse. Power is supplied from the 12V lithium auxiliary battery (20) to controllers within the vehicle, including the BMS (100), in the order of the current sensor, fuse, and latch relay.

In the present disclosure, the BMS 100 may be configured to perform an existing function of monitoring battery cells in the BMA 10, and may further be configured to monitor battery cells of the 12V lithium auxiliary battery 20.

Specifically, the BMS 100 may monitor the battery cell status (e.g., cell voltage and temperature) of the 12V lithium auxiliary battery 20 to determine the condition of the battery cells, may control an ON/OFF state of the latch relay in the PRA 30, and may monitor the output current of the 12V lithium auxiliary battery 20. The monitoring of the output current may be performed by converting a voltage received from a current sensor in the PRA 30 into a current.

FIG. 2 illustrates a circuit configuration of the integrated battery system (i.e. BSA) described above with reference to FIG. 1.

For convenience of illustration and explanation, FIG. 2 shows the circuit configuration of the BSA with a focus on the 12V lithium auxiliary battery 20.

As illustrated in FIG. 2, according to one embodiment of the present disclosure, in the BSA that includes the 12V lithium auxiliary battery 20, the BMS configured to monitor the battery cells in the high-voltage battery module, i.e., the BMA 10 of FIG. 1, may also be configured to monitor the battery cells of the 12V lithium auxiliary battery 20.

Specifically, the BMS may include a high-voltage cell monitoring unit (not shown) configured to monitor battery cells in the BMA 10, an auxiliary battery cell monitoring unit (12V auxiliary battery cell monitoring IC) configured to monitor battery cells of the 12V lithium auxiliary battery 20, and a controller (Main MCU) configured to determine the cell conditions of the BMA 10 and the 12V lithium auxiliary battery 20 based on monitoring information about the high-voltage cell monitoring unit and the auxiliary battery cell monitoring unit.

In addition, the BMS may include a power supply circuit 115 configured to receive power (B+_BATT power, 12V Aux.) from the 12V lithium auxiliary battery 20 and supply the power internally within the BMS.

As can be seen from FIG. 2, power from the 12V lithium auxiliary battery 20 may be output to a constant vehicle load through a current sensor followed by a fuse in the PRA 30. In addition, the power from the 12V lithium auxiliary battery 20 may also be output, in the order of the current sensor, the fuse, and the latch relay in the PRA 30, to a vehicle junction box positioned at the rear stage, and then to a non-constant vehicle load. The latch relay may be intended to interrupt current.

Structurally, the negative terminal of the 12V lithium auxiliary battery 20 may be connected to BSA_CHASSIS_GND. When the 12V lithium auxiliary battery 20 is mounted in a vehicle, the negative terminal may be connected to VEHICLE_CHASSIS_GND through a separate installation cable.

As described above, the battery management system equipped with the auxiliary battery cell monitoring function according to one embodiment of the present disclosure may be applied to the BSA having the structure and circuit configuration described with reference to FIGS. 1 and 2.

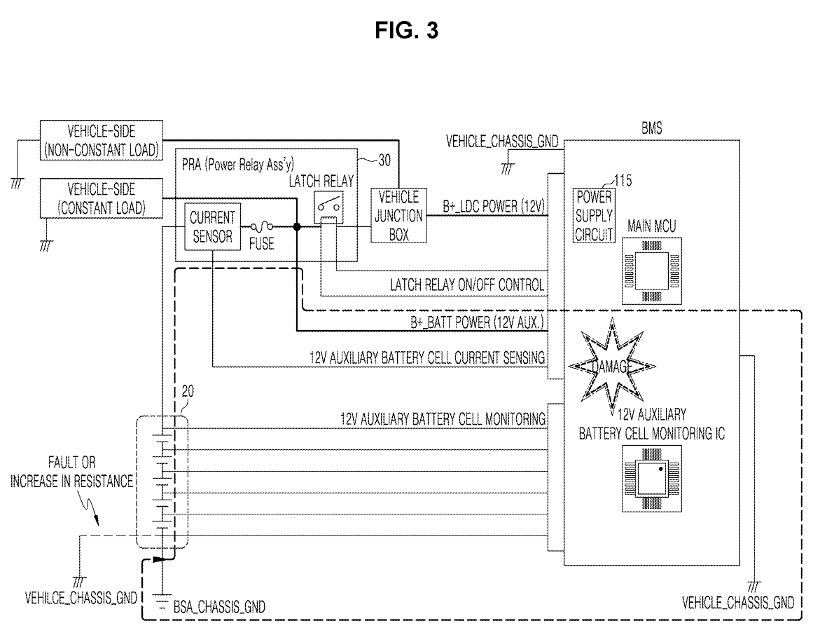

FIG. 3 illustrates a potential problem that may occur in the structure and circuit configuration of the BSA according to one embodiment of the present disclosure.

In the BSA according to one embodiment of the present disclosure, the BMS that monitors the battery cells in the BMA 10 may also be configured to monitor the battery cells of the 12V lithium auxiliary battery 20. The BMS may have a power path configured to receive power (B+_BATT power, 12V Aux.) from the 12V lithium auxiliary battery 20.

In addition, the negative terminal of the 12V lithium auxiliary battery 20 may be connected to BSA_CHASSIS_GND. When the 12V lithium auxiliary battery 20 is mounted in the vehicle, the negative terminal may be connected to VEHICLE_CHASSIS_GND through a separate installation cable.

Accordingly, the GND of the auxiliary battery cell monitoring unit (12V auxiliary battery cell monitoring IC) configured to monitor the battery cells of the 12V lithium auxiliary battery 20 in the BMS is connected to VEHICLE_CHASSIS_GND when the 12V lithium auxiliary battery 20 is mounted in the vehicle, and to BSA_CHASSIS_GND when the 12V lithium auxiliary battery 20 is not mounted in the vehicle.

According to the structure and circuit configuration of the BSA, when the BSA is in a standalone state separated from the vehicle, that is, when the 12V lithium auxiliary battery 20 is not mounted in the vehicle, different GNDs - BSA_CHASSIS_GND and VEHICLE_CHASSIS_GND - may be electrically connected within the board of the BMS.

When BSA_CHASSIS_GND and VEHICLE_CHASSIS_GND become electrically connected within the board of the BMS as described above, a leakage current may flow even in the standalone state of the BSA, potentially resulting in the discharge of the 12V lithium auxiliary battery 20.

In addition, when the 12V lithium auxiliary battery 20 is mounted in the vehicle, an increase in resistance may occur in the installation cable used for connection due to the cable disconnection, bolting fault, or the like. In such a case, the load current of the 12V lithium auxiliary battery 20 may not flow to VEHICLE_CHASSIS_GND through the negative terminal, but instead may flow into the BMS board, which may result in a risk of damage to the BMS.

To date, in the integrated battery system (BSA) including the auxiliary battery, although the BMS configured to monitor the battery cells in a high-voltage battery module is also equipped with the function of monitoring the battery cells of the auxiliary battery, there has been no concrete technical solution for preventing situations such as the discharge of the auxiliary battery in the standalone state of the BSA or the damage to the BMS caused by the installation cable or bolting fault, and for ensuring stable operation of the BMS.

One embodiment of the present disclosure may propose the battery management system (BMS) equipped with the auxiliary battery cell monitoring function, which may prevent problem situations such as auxiliary battery discharge and BMS damage during auxiliary battery cell monitoring in the above-described integrated battery system (BSA), and operate in a stable manner.

A battery management system (BMS) equipped with an auxiliary battery cell monitoring function according to one embodiment of the present disclosure may include a power supply circuit configured to receive power from an auxiliary battery and supply the power to the battery management system, a controller configured to determine states of battery cells of a high-voltage battery module and the auxiliary battery based on information obtained by monitoring the battery cells of the high-voltage battery module and the battery cells of the auxiliary battery, and a separation circuit configured to prevent electrical connection between respective grounds (GNDs) of the power supply circuit and an auxiliary battery cell monitoring unit configured to monitor the battery cells of the auxiliary battery, based on a potential difference between the respective grounds.

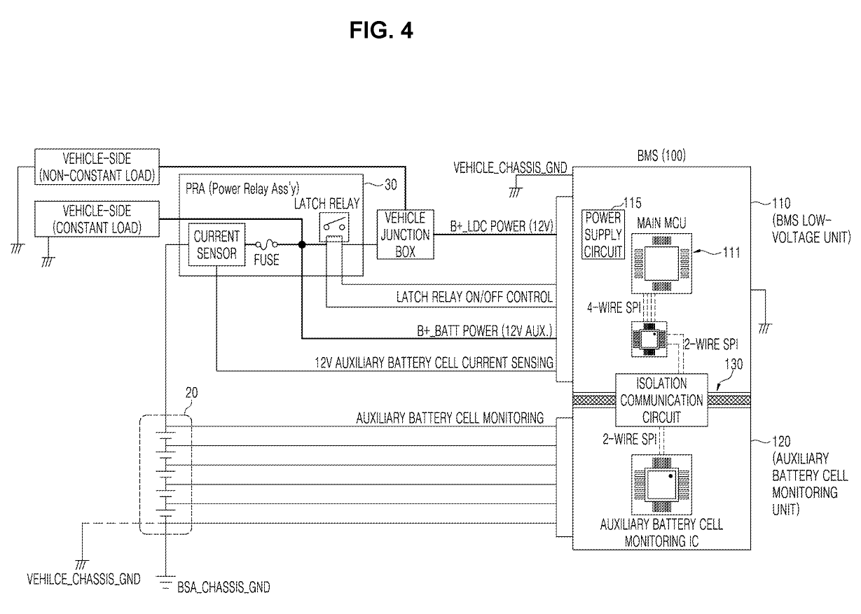

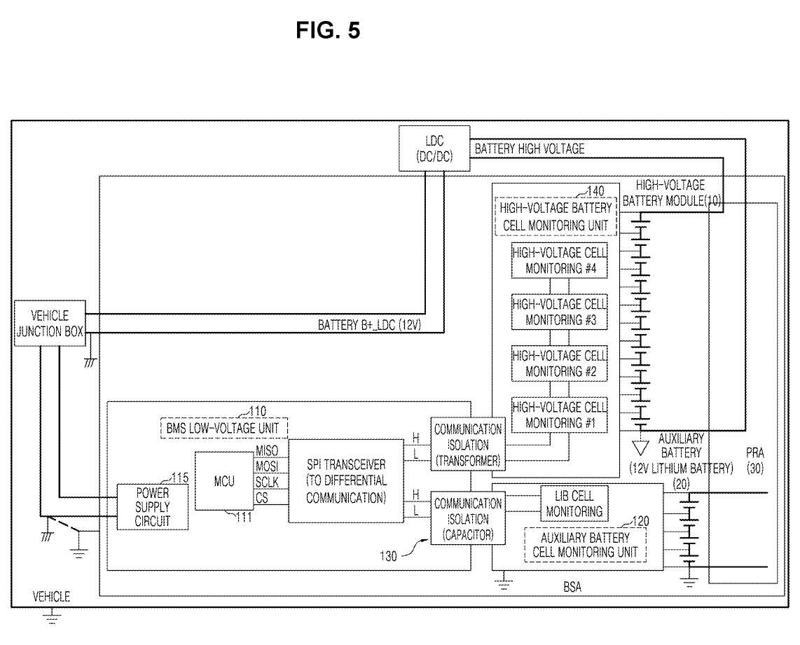

The separation circuit may include an isolation circuit configured to isolate the respective GNDs of the power supply circuit and the auxiliary battery cell monitoring unit (see FIGS. 4 and 5 below).

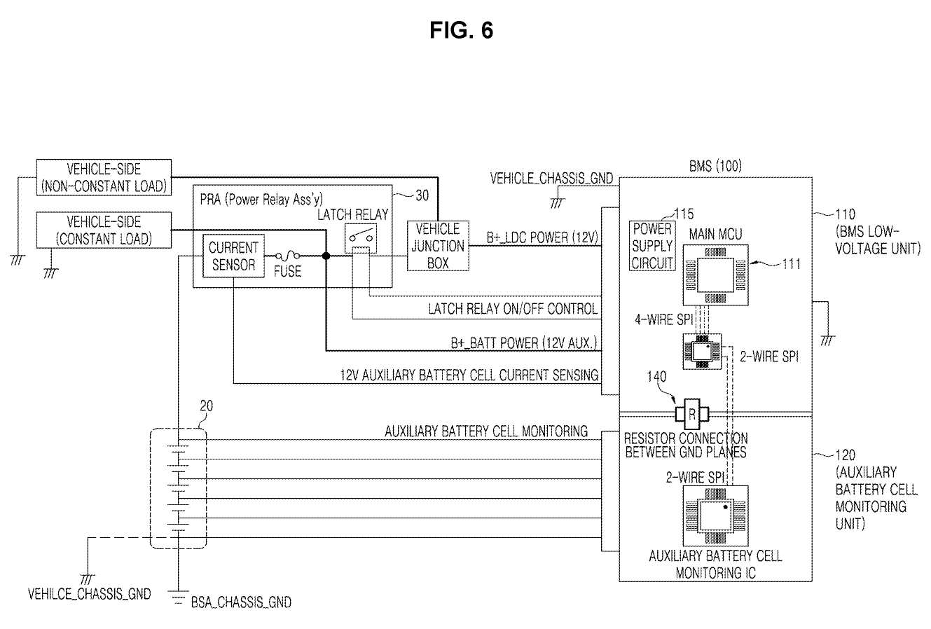

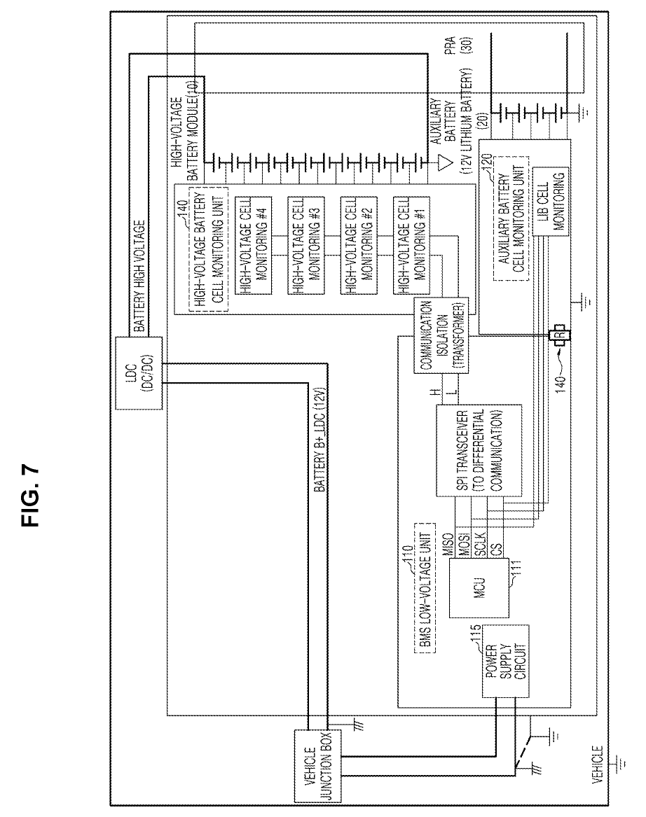

The separation circuit may include a non-isolation circuit configured to adjust a potential difference between the respective GNDs of the power supply circuit and the auxiliary battery cell monitoring unit (see FIGS. 6 and 7 below).

Hereinafter, with reference to FIGS. 4 and 5, an internal structure and circuit design of the BMS equipped with the auxiliary battery cell monitoring function according to one embodiment of the present disclosure will be described.

FIG. 4 illustrates one embodiment of the present disclosure in which an isolation circuit is incorporated within BMS 100 to prevent auxiliary battery discharge and BMS damage during auxiliary battery cell monitoring.

Referring to FIG. 4, the BMS 100 according to the present disclosure may include a power supply circuit 115 that receives power (B+_BATT power, 12V Aux.) from the 12V lithium auxiliary battery 20 and supplies the power within the BMS 100, and an auxiliary battery cell monitoring unit 120 configured to monitor the battery cells of the 12V lithium auxiliary battery 20.

The auxiliary battery cell monitoring unit 120 may include a circuit configured to monitor the voltage or the like of each of the plurality of battery cells in the 12V lithium auxiliary battery 20, and may include an auxiliary battery cell monitoring IC (e.g., BMIC: battery monitoring integrated circuit).

The BMS 100 according to one embodiment of the present disclosure may include an isolation circuit 130 configured to isolate the respective grounds (GNDs) of the power supply circuit 115 and the auxiliary battery cell monitoring unit 120.

As illustrated in FIG. 4, for convenience of explanation, the portion within the BMS 100 in which the power path for receiving B+_BATT power (12V Aux.), the power supply circuit 115, and the controller 111 (Main MCU) are located will be referred to as a BMS low-voltage unit 110.

Specifically, the isolation circuit 130 may be configured to provide isolation between the BMS low-voltage unit 110 and a portion of the BMS board where the auxiliary battery cell monitoring unit 120 is mounted. The isolation circuit 130 may also be configured to implement a communication path between the controller 111 and the auxiliary battery cell monitoring unit 120, particularly the auxiliary battery cell monitoring IC, using an isolation communication circuit.

Accordingly, the BMS 100 according to one embodiment of the present disclosure may isolate the respective grounds (GNDs) of the power supply circuit 115 and the auxiliary battery cell monitoring unit 120 through the isolation circuit 130. The isolation circuit 130 may include the above-described isolation communication circuit.

More specifically, as illustrated in FIG. 5, an isolation communication circuit may implement a communication path between a controller 111 (main MCU) and an auxiliary battery cell monitoring unit 120, particularly an auxiliary battery cell monitoring IC, using a communication isolation capacitor.

As such, according to one embodiment of the present disclosure, the BMS 100 may be configured to implement an internal structure and circuit design in which the respective grounds (GNDs) of the power supply circuit 115 and the auxiliary battery cell monitoring unit 120 are isolated through the isolation circuit 130.

Accordingly, according to embodiments of the present disclosure, it is possible to prevent the situation in which BSA_CHASSIS_GND and VEHICLE_CHASSIS_GND become electrically connected within the board of the BMS 100, thereby preventing the 12V lithium auxiliary battery 20 from being discharged even when the BSA 200 including the BMS 100 is in the standalone state.

In addition, according to embodiments of the present disclosure, it is possible to block the occurrence of a path through which the load current of the 12V lithium auxiliary battery 20 flows into the BMS 100, thereby preventing damage to the BMS caused by the inflow of the load current of the 12V lithium auxiliary battery 20, even when the installation cable or bolting fault occurs.

Meanwhile, in FIG. 5, a high-voltage battery cell monitoring unit, which is illustrated as a circuit for monitoring the battery cells of the high-voltage battery, i.e., the BMA 10, in the BMS 100 according to one embodiment of the present disclosure, and a communication structure between the controller 111 (main MCU) and the high-voltage battery cell monitoring unit are not different from those of existing technologies. Thus, a detailed description thereof will be omitted.

Hereinafter, with reference to FIGS. 6 and 7, an internal structure and circuit design of a BMS equipped with an auxiliary battery cell monitoring function according to another embodiment of the present disclosure will be described.

FIG. 6 illustrates another embodiment of the present disclosure, in which a solution for preventing problem situations such as auxiliary battery discharge and BMS damage during auxiliary battery cell monitoring is provided through a non-isolation circuit within a BMS 100.

Referring to FIG. 6, the BMS 100 according to the present disclosure may include a power supply circuit 115 that receives power (B+_BATT power, 12V Aux.) from a 12V lithium auxiliary battery 20 and supplies the power within the BMS 100, and an auxiliary battery cell monitoring unit 120 configured to monitor the battery cells of the 12V lithium auxiliary battery 20.

The auxiliary battery cell monitoring unit 120 may include a circuit configured to monitor the voltage or the like of each of the plurality of battery cells in the 12V lithium auxiliary battery 20, and may include an auxiliary battery cell monitoring IC (e.g., BMIC: battery monitoring integrated circuit).

The BMS 100 according to one embodiment of the present disclosure may include a non-isolation circuit 140 configured to adjust a potential difference between the respective grounds (GNDs) of the power supply circuit 115 and the auxiliary battery cell monitoring unit 120.

As illustrated in FIG. 6, the portion within the BMS 100 in which a power path for receiving B+_BATT power (12V Aux.), the power supply circuit 115, and the controller 111 (main MCU) are located will be referred to as a BMS low-voltage unit 110.

Specifically, the non-isolation circuit 140 may be implemented as a single-point grounding structure. In this structure, the GND plane of the BMS low-voltage unit 110, which includes the power supply circuit, and the GND plane of the auxiliary battery cell monitoring unit 120 may be connected at a single point using a resistor (R).

Accordingly, the BMS 100 according to one embodiment of the present disclosure may be configured to reduce and adjust the potential difference between the respective GNDs of the power supply circuit 115 and the auxiliary battery cell monitoring unit 120 through the non-isolation circuit 140, which is implemented as a single-point grounding structure using the resistor (R).

More specifically, as illustrated in FIG. 7, the non-isolation circuit 140 implemented as the single-point grounding structure using the resistor (R) may serve to match the ground potential levels between the respective GND planes of the BMS low-voltage unit 110 and the auxiliary battery cell monitoring unit 120. In addition, the resistor (R) may act as a fuse that blows upon the inflow of unexpected current, thereby preventing a short circuit between the GNDs of the BMS low-voltage unit 110 and the auxiliary battery cell monitoring unit 120.

As such, according to another embodiment of the present disclosure, the BMS 100 may be configured to implement an internal structure and circuit design that adjusts the potential difference between the respective GNDs of the power supply circuit 115 and the auxiliary battery cell monitoring unit 120 through the non-isolation circuit 140.

Accordingly, according to embodiments of the present disclosure, it is possible to block an electrical connection caused by a potential difference between BSA_CHASSIS_GND and VEHICLE_CHASSIS_GND within the board of the BMS 100 by matching the ground potential levels, thereby preventing the 12V lithium auxiliary battery 20 from being discharged even when the BSA 200 including the BMS 100 is in the standalone state.

In addition, according to embodiments of the present disclosure, a path of the load current from the 12V lithium auxiliary battery (20) into the BMS 100 may be blocked by a fuse function. Accordingly, even when the installation cable or bolting fault occurs, damage to the BMS caused by the inflow of load current from the auxiliary battery may be prevented.

In particular, as illustrated in FIGS. 6 and 7, the non-isolation circuit according to embodiments of the present disclosure may achieve the same effect as the isolation circuit described above, with a lower-cost circuit configuration.

Meanwhile, in FIG. 7, a high-voltage battery cell monitoring unit, which is illustrated as a circuit for monitoring the battery cells of the high-voltage battery, i.e., the BMA 10, in the BMS 100 according to one embodiment of the present disclosure, and a communication structure between the controller 111 (Main MCU) and the high-voltage battery cell monitoring unit are not different from those of existing technologies. Thus, a detailed description thereof will be omitted.

According to the various embodiments of the present disclosure described above, in the integrated battery system including the high-voltage battery module and the 12V lithium auxiliary battery, a specific technical solution may be provided that enables the BMS to monitor not only the battery cells of the high-voltage battery module but also the battery cells of the auxiliary battery, and to operate in a stable manner.

Accordingly, embodiments of the present disclosure may provide an effect of preventing an auxiliary battery from being discharged in the standalone state of the integrated battery system and, furthermore, preventing damage to the BMS board caused by load current from the auxiliary battery flowing into the BMS board due to a fault in the installation cable or bolting (e.g., cable disconnection or increased resistance).

As used in the present disclosure (especially in the appended claims), the terms "a/an" and "the" include both singular and plural references, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. All examples described in the present disclosure or the terms indicative thereof ("for example", "such as") are merely to describe the present disclosure in greater detail. Therefore, it should be understood that the scope of the present disclosure is not limited to the example embodiments described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the example embodiments described above, and rather intended to include the following appended claims, and all modifications, equivalents, and alternatives falling within the spirit and scope of the following claims.

The present disclosure described as above is not limited by the aspects described herein and the accompanying drawings. It should be apparent to those skilled in the art that various substitutions, changes and modifications which are not exemplified herein but are still within the spirit and scope of the present disclosure may be made. Therefore, the scope of the present disclosure is defined not by the detailed description, but by the claims and their equivalents, and all variations within the scope of the claims and their equivalents are to be construed as being included in the present disclosure.

1. A battery management system (BMS), the battery management system comprising:
a power supply circuit configured to receive power from an auxiliary battery and to supply the power to the battery management system;
a controller configured to determine a state of each of a plurality of battery cells of a high-voltage battery module and a state of the auxiliary battery based on information obtained by monitoring the plurality of battery cells of the high-voltage battery module and the plurality of battery cells of the auxiliary battery; and
a separation circuit configured to prevent electrical connection between a ground (GND) of the power supply circuit and a ground of an auxiliary battery cell monitoring unit configured to monitor the plurality of battery cells of the auxiliary battery, based on a potential difference between the ground of the power supply circuit and the ground of the auxiliary battery cell monitoring unit.

2. The battery management system of claim 1, wherein the separation circuit comprises an isolation circuit configured to isolate the ground of the power supply circuit and the ground of the auxiliary battery cell monitoring unit.

3. The battery management system of claim 1, wherein the GND of the power supply circuit is VEHICLE_CHASSIS_GND, and the GND of the auxiliary battery cell monitoring unit is connected to the VEHICLE_CHASSIS_GND when the auxiliary battery is mounted in a vehicle, and wherein the GND of the auxiliary battery cell monitoring unit is connected to a BSA (battery system assembly)_CHASSIS_GND when the auxiliary battery is not mounted in the vehicle.

4. The battery management system of claim 2, wherein the isolation circuit is configured to isolate, on a board of the BMS, a portion where the power supply circuit and the controller are mounted from a portion where the auxiliary battery cell monitoring unit is mounted, to provide a communication path between the controller and the auxiliary battery cell monitoring unit using an isolation communication circuit, and to isolate the ground of the power supply circuit and the ground of the auxiliary battery cell monitoring unit.

5. The battery management system of claim 4, wherein the isolation communication circuit is configured to provide the communication path between the controller and the auxiliary battery cell monitoring unit using a communication isolation capacitor.

6. The battery management system of claim 3, wherein a negative terminal of the auxiliary battery is connected to the BSA_CHASSIS_GND, and is connected to the VEHICLE_CHASSIS_GND via a separate installation cable when the auxiliary battery is mounted in the vehicle.

7. The battery management system of claim 1, wherein the separation circuit comprises a non-isolation circuit configured to adjust a potential difference between the ground of the power supply circuit and the ground of the auxiliary battery cell monitoring unit.

8. The battery management system of claim 7, wherein the non-isolation circuit is configured to connect a GND plane of the power supply circuit and a GND plane of the auxiliary battery cell monitoring unit at a single point using a resistor, and is configured to reduce a potential difference between the ground of the power supply circuit and the ground of the auxiliary battery cell monitoring unit through the resistor.

9. The battery management system of claim 7, wherein the GND of the power supply circuit is VEHICLE_CHASSIS_GND, and the GND of the auxiliary battery cell monitoring unit is connected to the VEHICLE_CHASSIS_GND when the auxiliary battery is mounted in a vehicle, and wherein the GND of the auxiliary battery cell monitoring unit is connected to a BSA (battery system assembly)_CHASSIS_GND when the auxiliary battery is not mounted in the vehicle.

10. The battery management system of claim 9, wherein a negative terminal of the auxiliary battery is connected to the BSA_CHASSIS_GND, and is connected to the VEHICLE_CHASSIS_GND via a separate installation cable when the auxiliary battery is mounted in the vehicle.

11. A battery management system for managing an integrated battery system assembly (BSA) comprising a high-voltage battery module and an auxiliary battery, the battery management system comprising:
a power supply circuit configured to receive power from the auxiliary battery and to supply the power to the battery management system (BMS); and
an isolation circuit configured to isolate a ground (GND) of the power supply circuit and a ground of an auxiliary battery cell monitoring unit configured to monitor battery cells of the auxiliary battery, to prevent electrical connection between the ground of the power supply circuit and the ground of the auxiliary battery cell monitoring unit within a board of the BMS when the auxiliary battery is not mounted in a vehicle, and is further configured to prevent a load current of the auxiliary battery from flowing into the board of the BMS when the auxiliary battery is mounted in the vehicle.

12. The battery management system of claim 11, wherein the isolation circuit is configured to isolate, on the board of the BMS, a portion where the power supply circuit and a controller are mounted from a portion where the auxiliary battery cell monitoring unit is mounted, and is further configured to provide a communication path between the controller and the auxiliary battery cell monitoring unit using an isolation communication circuit.

13. The battery management system of claim 12, wherein the isolation communication circuit is configured to provide the communication path between the controller and the auxiliary battery cell monitoring unit using a communication isolation capacitor.

14. A battery management system for managing an integrated battery system assembly (BSA) comprising a high-voltage battery module and an auxiliary battery, the battery management system comprising:
a power supply circuit configured to receive power from the auxiliary battery and to supply the power to the battery management system (BMS); and
a non-isolation circuit configured to adjust a potential difference between a ground (GND) of the power supply circuit and a ground of an auxiliary battery cell monitoring unit configured to monitor battery cells of the auxiliary battery, to prevent electrical connection between the ground of the power supply circuit and the ground of the auxiliary battery cell monitoring unit within a board of the BMS when the auxiliary battery is not mounted in a vehicle, and further configured to prevent a load current of the auxiliary battery from flowing into the board of the BMS when the auxiliary battery is mounted in the vehicle.

15. The battery management system of claim 14, wherein the non-isolation circuit is configured to connect a GND plane of the power supply circuit and a ground plane of the auxiliary battery cell monitoring unit at a single point using a resistor.

16. The battery management system of claim 15, wherein the GND of the power supply circuit is VEHICLE_CHASSIS_GND, and the GND of the auxiliary battery cell monitoring unit is connected to the VEHICLE_CHASSIS_GND when the auxiliary battery is mounted in a vehicle, and wherein the GND of the auxiliary battery cell monitoring unit is connected to a BSA (battery system assembly)_CHASSIS_GND when the auxiliary battery is not mounted in the vehicle.

17. The battery management system of claim 16, wherein a negative terminal of the auxiliary battery is connected to the BSA_CHASSIS_GND, and is connected to the VEHICLE_CHASSIS_GND via a separate installation cable when the auxiliary battery is mounted in the vehicle.
